(19) United States
(12) Patent Application Publication
(10) Pub. No.: US 2026/0318952 A1
(43) Pub. Date: Oct. 15, 2026

(54) FIBER ARRAY UNITS FOR OPTICALLY TESTING A PLURALITY OF OPTICAL DEVICES OF A DEVICE UNDER TEST, OPTICAL PROBE ASSEMBLIES THAT INCLUDE THE FIBER ARRAY UNITS, OPTICAL PROBE SYSTEMS THAT INCLUDE THE OPTICAL PROBE ASSEMBLIES, AND RELATED METHODS

(71) Applicant: FormFactor, Inc., Livermore, CA (US)

(72) Inventors: Quan Yuan, Dublin, CA (US); Divya Pratap, Beaverton, OR (US)

(21) Appl. No.: 19/569,800

(22) Filed: Mar. 17, 2026

Related U.S. Application Data
(60) Provisional application No. 63/786,836, filed on Apr. 10, 2025.

(51) Int. Cl. G01R 1/07

(52) U.S. Cl. CPC G01R 1/071

(57) ABSTRACT

Fiber array units for optically testing a plurality of optical devices of a device under test (DUT), optical probe assemblies that include the fiber array units, optical probe systems that include the optical probe assemblies, and related methods. The fiber array units include a support body and a plurality of fiber optic conduits supported by the support body and configured to convey a plurality of electromagnetic signals. The fiber array units also include a signal transmission structure configured to transmit the plurality of electromagnetic signals between the plurality of fiber optic conduits and the plurality of optical devices, and a mechanical coupling structure configured to mechanically couple the fiber array unit to the DUT and to maintain a transmission gap between the signal transmission structure and the plurality of optical devices. The optical probe assemblies and the optical probe systems include the fiber array units.

### RELATED APPLICATION

This application claims priority to U.S. Provisional Patent Application No. 63/786,836, which was filed on Apr. 10, 2025, and the complete disclosure of which is hereby incorporated by reference.

### FIELD OF THE DISCLOSURE

The present disclosure is directed generally to fiber array units for optically testing a plurality of optical devices of a device under test, to optical probe assemblies that include the fiber array units, to optical probe systems that include the optical probe assemblies, and to related methods.

### BACKGROUND OF THE DISCLOSURE

Optical probe systems may be utilized to test, such as to optically test, a device under test (DUT) that includes optical devices. In general, such testing is performed by aligning one or more optical probes of the optical probe system relative to one or more optical devices of the DUT such that electromagnetic signals may be conveyed between the one or more optical probes and the one or more optical devices via an air gap therebetween. Alignment between the one or more optical probes and the one or more optical devices is significantly impacted by relative motion therebetween, such as may be caused by environmental vibration within a testing environment that surrounds the optical probe system. Vibration isolation structures generally are utilized to vibrationally isolate conventional optical probe systems from the testing environment. While effective, such vibration isolation structures generally are complex and expensive, and it may not be feasible to utilize such vibration isolation structures in all testing environments and/or to retrofit existing testing environments to include such vibration isolation structures. Thus, there exists a need for improved fiber array units for optically testing a plurality of optical devices of a device under test, optical probe assemblies that include the fiber array units, optical probe systems that include the optical probe assemblies, and related methods.

### SUMMARY OF THE DISCLOSURE

Fiber array units for optically testing a plurality of optical devices of a device under test (DUT), optical probe assemblies that include the fiber array units, optical probe systems that include the optical probe assemblies, and related methods. The fiber array units include a support body and a plurality of fiber optic conduits supported by the support body and configured to convey a plurality of electromagnetic signals. The fiber array units also include a signal transmission structure configured to transmit the plurality of electromagnetic signals between the plurality of fiber optic conduits and the plurality of optical devices, and a mechanical coupling structure configured to mechanically couple the fiber array unit to the DUT and to maintain a transmission gap between the signal transmission structure and the plurality of optical devices.

The optical probe assemblies include a fiber array unit and an array unit fixture. The array unit fixture is configured to be operatively attached to the fiber array unit and to support the fiber array unit.

The optical probe systems include an optical probe assembly and a DUT support fixture. The DUT support fixture is configured to operatively support the DUT relative to the optical probe assembly. The optical probe systems also include an electromagnetic signal generation and analysis assembly. The electromagnetic signal generation and analysis assembly is configured to at least one of provide at least a provided subset of the plurality of electromagnetic signals to a corresponding providing subset of the plurality of fiber optic conduits and receive at least a received subset of the plurality of electromagnetic signals from a corresponding receiving subset of the plurality of fiber optic conduits.

The methods are methods of optically probing a device under test (DUT) and include positioning a signal transmission structure of a fiber array unit of an optical probe system relative to the DUT such that a mechanical coupling structure of the fiber array unit is spaced apart from the DUT by an alignment separation distance. Subsequent to the positioning, the methods also include optically aligning the signal transmission structure with a plurality of optical devices of the DUT to define an aligned-and-spaced relative orientation between the signal transmission structure and the plurality of optical devices. Subsequent to the optically aligning, the methods further include offsetting the signal transmission structure from the aligned-and-spaced relative orientation to an offset relative orientation that is based, at least in part, on both the alignment separation distance and a transmission angle of a signal transmission axis of the signal transmission structure. The methods also include physically contacting the mechanical coupling structure with the DUT to define an aligned-and-contacted relative orientation between the signal transmission structure and the plurality of optical devices in which there is a transmission gap between the signal transmission structure and the plurality of optical devices. The methods further include optically probing the DUT utilizing the fiber array unit.

### BRIEF DESCRIPTION OF THE DRAWINGS

FIG. 1 is a schematic front view illustrating examples of a fiber array unit for optically testing a plurality of optical devices of a device under test, of optical probe assemblies that include the fiber array units, and/or of optical probe systems that include the optical probe assemblies, according to the present disclosure.

FIG. 2 is a less schematic illustration of an example of a region of an optical probe assembly that includes a fiber array unit, according to the present disclosure.

FIG. 3 is a more detailed illustration of a region of the fiber array unit of FIG. 2 that is indicated by dashed box 3 in FIG. 2.

FIG. 4 is a less schematic side view illustrating an example of a fiber array unit in the form of a lensed fiber array, according to the present disclosure.

FIG. 5 is a less schematic side view illustrating an example of a fiber array unit in the form of a polished fiber array, according to the present disclosure.

FIG. 6 is another illustration of the fiber array unit of FIG. 5.

FIG. 7 is another illustration of the fiber array unit of FIG. 5.

FIG. 8 is another illustration of the fiber array unit of FIG. 5.

FIG. 9 is a plot illustrating a plurality of frequency sweeps performed by a conventional optical probe system.

FIG. 10 is a plot illustrating a plurality of frequency sweeps performed utilizing an optical probe system that includes an optical probe assembly that includes a fiber array unit, according to the present disclosure.

FIG. 11 is a flowchart depicting examples of methods, according to the present disclosure, of optically probing a device under test.

### DETAILED DESCRIPTION AND BEST MODE OF THE DISCLOSURE

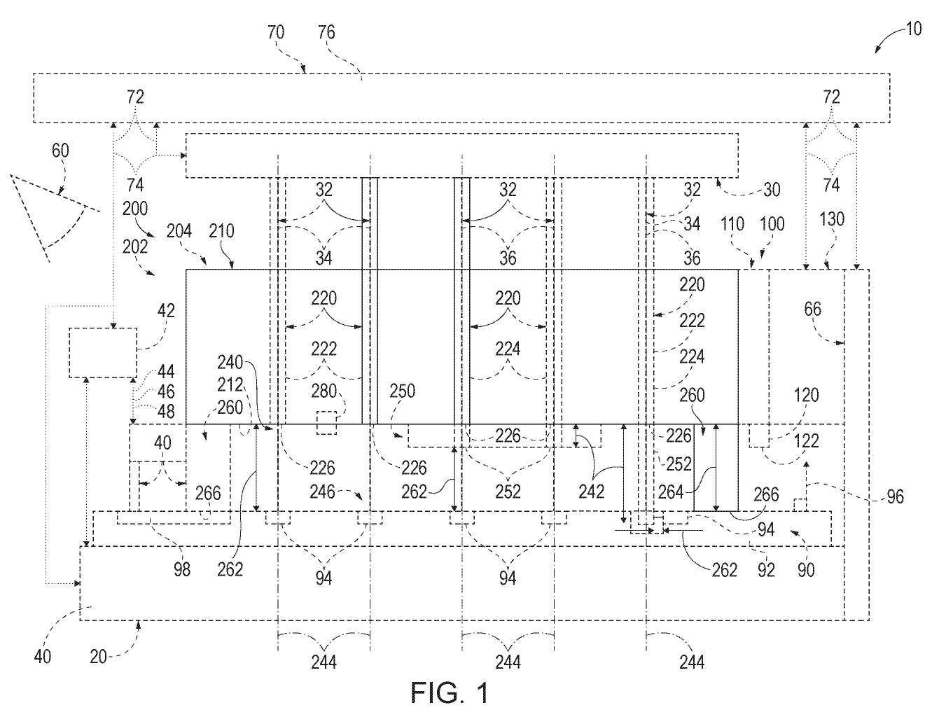

FIGS. 1-11 provide examples of fiber array units 200 for optically testing a plurality of optical devices 94 of a device under test (DUT) 92, of optical probe assemblies 100 that include the fiber array units, of optical probe systems 10 that include the optical probe assemblies, and of methods 300 of optically probing a device under test (DUT), according to the present disclosure. Elements that serve a similar, or at least substantially similar, purpose are labeled with like numbers in each of FIGS. 1-11, and these elements may not be discussed in detail herein with reference to each of FIGS. 1-11. Similarly, all elements may not be labeled in each of FIGS. 1-11, but reference numerals associated therewith may be utilized herein for consistency. Elements, components, and/or features that are discussed herein with reference to one or more of FIGS. 1-11 may be included in and/or utilized with any of FIGS. 1-11 without departing from the scope of the present disclosure.

In general, elements that are likely to be included in a particular embodiment are illustrated in solid lines, while elements that may be optional are illustrated in dashed lines. However, elements that are shown in solid lines may not be essential to all embodiments and, in some embodiments, may be omitted without departing from the scope of the present disclosure.

As illustrated in FIG. 1, optical probe systems 10 include an optical probe assembly 100, a DUT support fixture 20, and an electromagnetic signal generation and analysis assembly 30. Optical probe systems 10 may be configured to optically test a plurality of optical devices 94 of a DUT 92. DUT support fixture 20 may be configured to operatively support DUT 92 relative to optical probe assembly 100.

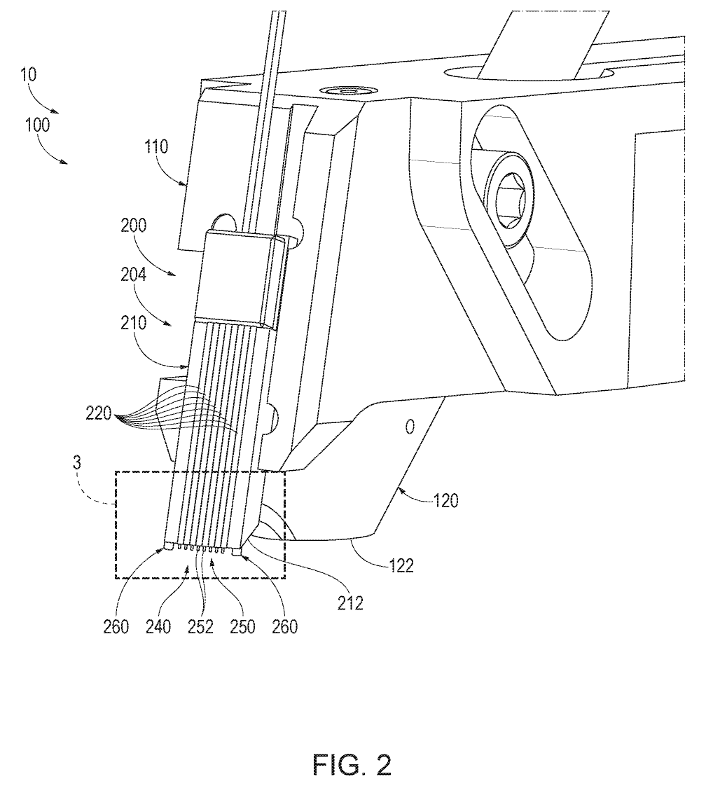

As discussed in more detail herein, and as collectively illustrated by FIGS. 1-2, optical probe assembly 100 includes a fiber array unit 200 and an array unit fixture 110. The array unit fixture may be configured to be operatively attached to the fiber array unit and/or to support the fiber array unit, such as relative to a remainder of the optical probe system.

As also discussed in more detail herein, and as collectively illustrated by FIGS. 1-8, fiber array unit 200 includes a support body 210 and a plurality of fiber optic conduits 220, which may be supported by the support body and/or may be configured to convey a plurality of electromagnetic signals 32. Fiber array unit 200 also includes a signal transmission structure 240 and a mechanical coupling structure 260. The signal transmission structure may be configured to transmit the plurality of electromagnetic signals 32 between the plurality of fiber optic conduits 220 and the plurality of optical devices 94. The mechanical coupling structure may be configured to mechanically couple, to directly couple, and/or to directly mechanically couple fiber array unit 200 to DUT 92 and/or to maintain a transmission gap 262 between signal transmission structure 240 and optical devices 94 and/or DUT 92.

Returning more specifically to FIG. 1, electromagnetic signal generation and analysis assembly 30 may be configured to provide at least a provided subset 34 of the plurality of electromagnetic signals 32 to a corresponding providing subset 222 of the plurality of fiber optic conduits 220. Additionally or alternatively, electromagnetic signal generation and analysis assembly 30 may be configured to receive at least a received subset 36 of the plurality of electromagnetic signals 32 from a corresponding receiving subset 224 of the plurality of fiber optic conduits 220.

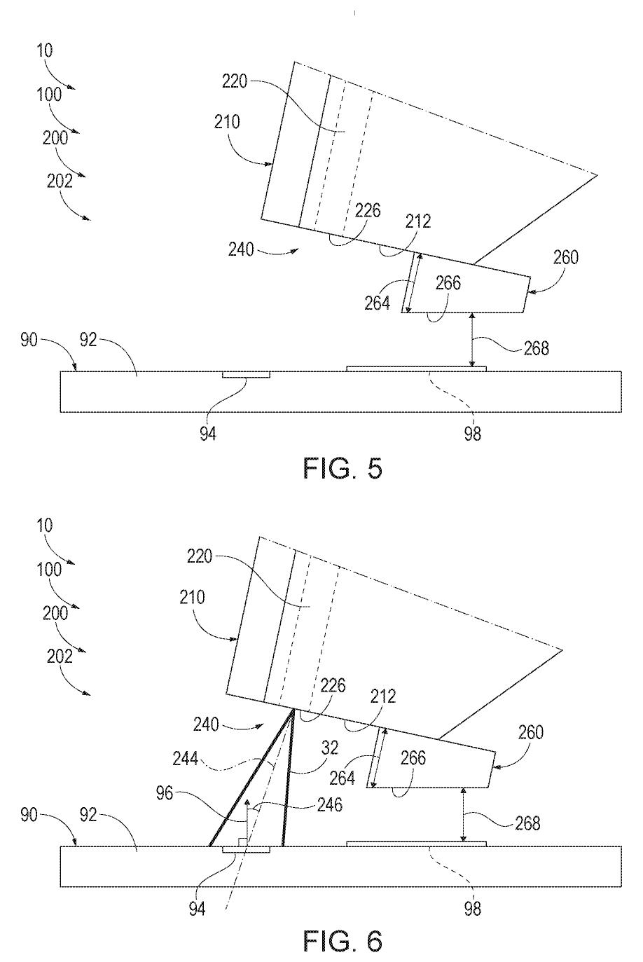

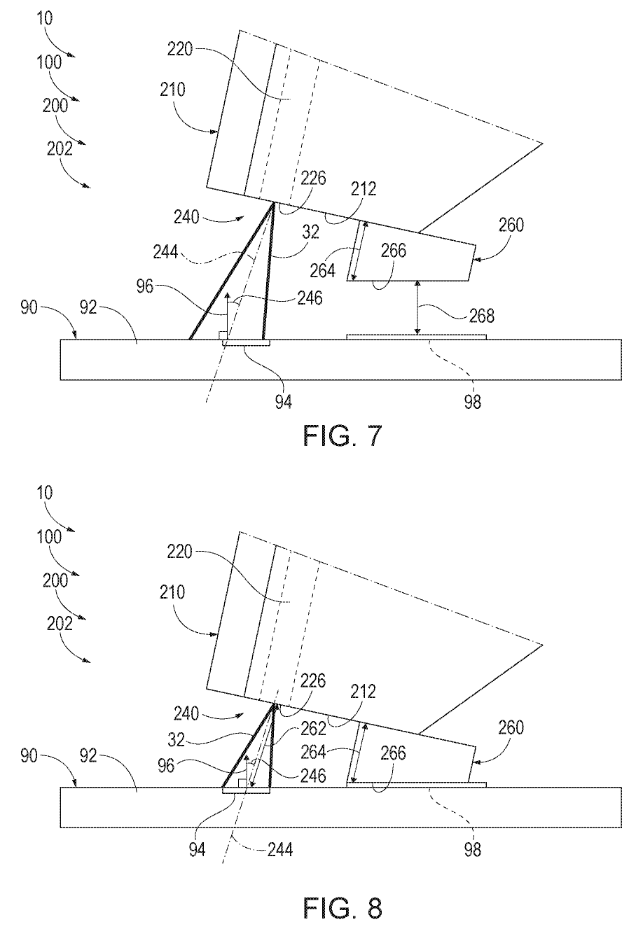

During operative use of optical probe systems 10, and as discussed in more detail herein with reference to methods 300, signal transmission structure 240 may be positioned relative to DUT 92 such that mechanical coupling structure 260 is spaced apart from the DUT, such as by an alignment separation distance 268, as illustrated in FIG. 5. Subsequently, signal transmission structure 240 may be optically aligned with a plurality of optical devices 94 thereof, such as via moving the signal transmission structure and the DUT relative to one another in the direction of the arrow illustrated in FIG. 6. This may include alignment to define an aligned-and-spaced relative orientation between the signal transmission structure and the plurality of optical devices. Then, the signal transmission structure may be offset from the aligned-and-spaced relative orientation, as illustrated in FIG. 7. This may include being offset to define an offset relative orientation that may be based, at least in part, on alignment separation distance 268 and/or on a transmission angle 246 of a signal transmission axis 244 of fiber array unit 200. Mechanical coupling structure 260 then may be brought into contact with DUT 92, as illustrated in FIG. 8, prior to optically probing the DUT utilizing the fiber array unit.

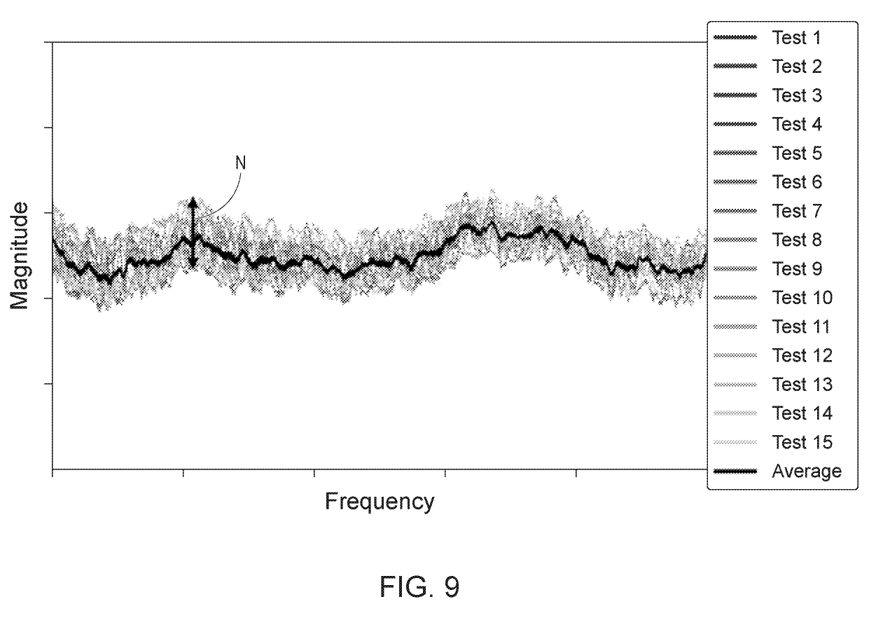

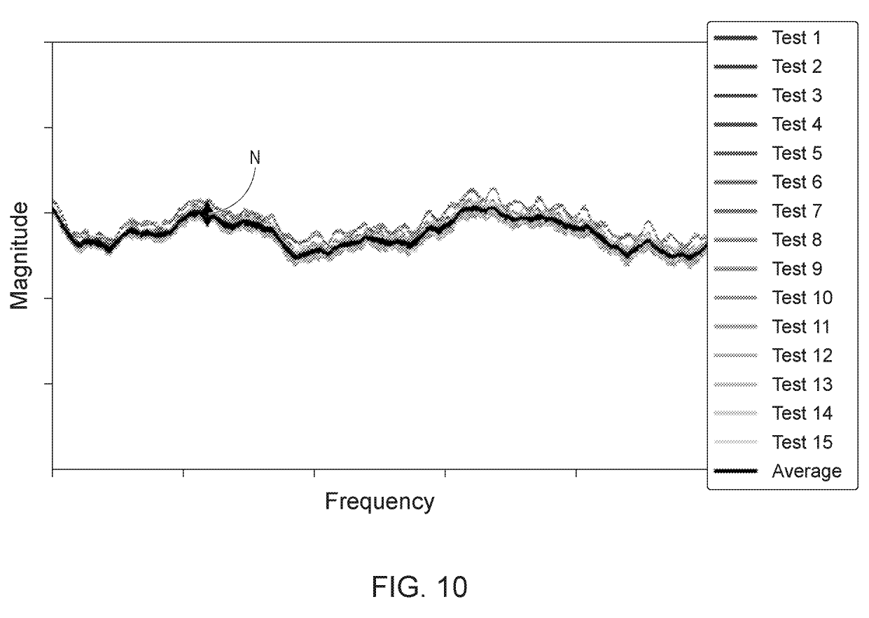

The physical contact between mechanical coupling structure 260 and DUT 92 may decrease a potential for relative motion between optical probe assembly 100, or signal transmission structure 240 thereof, and optical devices 94 of DUT 92, thereby decreasing measurement noise and/or increasing a signal-to-noise ratio for signals conveyed between DUT 92 and signal transmission structure 240 during the optical probing. Benefits of fiber array units 200 that include mechanical coupling structures 260, according to the present disclosure, are illustrated by a comparison between FIGS. 9 and 10. These two Figures are on the same scale, with FIG. 9 being a plot that illustrates a plurality of frequency sweeps performed by a conventional optical probe system that does not include fiber array units 200 and/or mechanical coupling structures 260, according to the present disclosure. In contrast, FIG. 10 is a plot illustrating a plurality of frequency sweeps performed utilizing optical probe system 10 that includes optical probe assembly 100 that includes fiber array unit 200 with mechanical coupling structures 260, according to the present disclosure. As clearly may be seen, a magnitude of noise and/or variation, N, is reduced substantially in optical probe systems 10, according to the present disclosure, when compared to conventional optical probe systems. This decrease in noise and/or variation may be caused by mechanical coupling between DUT 92 and fiber array unit 200, via mechanical coupling structure 260, which decreases relative motion therebetween.

DUT support fixture 20 may include any suitable structure that may be adapted, configured, designed, and/or constructed to operatively support DUT 92 relative to optical probe assembly 100. In some examples, DUT support fixture 20 may be configured to operatively support DUT 92 in the form of a singulated DUT and/or a packaged DUT. In such examples, DUT support fixture 20 also may be referred to herein as and/or may be a DUT package and/or a packaged DUT socket. In some examples, DUT support fixture 20 may be configured to support a substrate 90 that includes a plurality of DUTs 92. In such examples, DUT support fixture 20 also may be referred to herein as a chuck. Examples of the chuck include a wafer chuck, a shielded chuck, an electromagnetically shielded chuck, a thermal chuck, a temperature-controlled chuck, an electrostatic chuck, and/or a vacuum chuck.

Electromagnetic signal generation and analysis assembly 30 may include any suitable structure that may be adapted, configured, designed, and/or constructed to provide one or more electromagnetic signals 32 to fiber optic conduits 220 and/or receive the electromagnetic signals from the fiber optic conduits. Examples of electromagnetic signal generation and analysis assembly 30 include an electromagnetic signal generator, an electromagnetic signal source, a light source, a laser, a laser light source, an electromagnetic signal detector, and/or an electromagnetic signal analyzer.

In some examples, and as illustrated in dashed lines in FIG. 1, optical probe system 10 may include at least one electrical probe 40. Electrical probe 40, when present, may be adapted, configured, designed, and/or constructed to electrically contact DUT 92, to provide an electric test signal 44 to the DUT, to provide an electric power signal 46 to the DUT, and/or to receive an electric resultant signal 48 from the DUT. Examples of electrical probe 40 include an electrically conductive probe, a biased electrical probe, and/or a resilient electrical probe. In some examples, mechanical coupling structure 260 may define electrical probe 40. Additionally or alternatively, electrical probe 40 may be separate and/or distinct from the mechanical coupling structure. Additionally or alternatively, electrical probe 40 may be defined by DUT support fixture 20. It is within the scope of the present disclosure that electrical probe 40 may be configured to electrically contact a front, or a top, side of DUT 92 and/or of substrate 90, such as via contact with an electrical contact pad 98 of the DUT. Additionally or alternatively, electrical probe 40 may be configured to electrically contact a back, or a bottom, side of DUT 92, such as when DUT support fixture 20 defines the electrical probe.

In some examples, and as also illustrated in dashed lines in FIG. 1, optical probe systems 10 may include an electrical signal generation and analysis assembly 42. Electrical signal generation and analysis assembly 42, when present, may be adapted, configured, designed, and/or constructed to provide electric test signal 44 to electrical probe 40, to provide electric power signal 46 to the electrical probe, and/or to receive electric resultant signal 48 from the electrical probe. Examples of electrical signal generation and analysis assembly 42 include an electric power source, an AC power source, a DC power source, an electric function generator, an electric current meter, an electric voltage meter, and/or an electric signal analyzer.

In some examples, and as illustrated in dashed lines in FIG. 1, optical probe systems 10 may include an optical assembly 60. Optical assembly 60 may be adapted, configured, designed, and/or constructed to collect an optical image of one or more components of and/or utilized with optical probe system 10. As examples, optical assembly 60 may be configured to collect the optical image of DUT support fixture 20, one or more electrical probes 40, DUT 92, optical devices 94, electrical contact pad 98, fiber array unit 200, signal transmission structure 240, and/or a fiducial 280 of the fiber array unit. Examples of optical assembly 60 include a microscope, an optical microscope, an electronic microscope, a magnifying assembly, a camera, and/or a digital camera.

In some examples, and as also illustrated in dashed lines in FIG. 1, optical probe system 10 may include a positioning structure 66. Positioning structure 66 may be adapted, configured, designed, and/or constructed to translate and/or rotate fiber array unit 200 and DUT support fixture 20 relative to one another, such as to translate and/or rotate signal transmission structure 240 relative to optical devices 94 and/or to translate and/or rotate electrical probe 40 relative to electrical contact pad 98. This may include translation and/or rotation of fiber array unit 200 relative to DUT support fixture 20, translation and/or rotation of DUT support fixture 20 relative to fiber array unit 200, and/or translation and/or rotation of one or more electrical probes 40 relative to DUT support fixture 20. Examples of positioning structure 66 include an actuator, a linear actuator, a rotary actuator, a lead screw and nut assembly, a ball screw and nut assembly, a rack and pinion assembly, a piezoelectric actuator, a motor, a servo motor, a stepper motor, and/or a linear motor.

In some examples, and as illustrated in dashed lines in FIG. 1, optical probe system 10 may include a controller 70. Controller 70 may be adapted, configured, designed, and/or constructed to control the operation of one or more other components of the optical probe system, such as of DUT support fixture 20, electromagnetic signal generation and analysis assembly 30, electrical signal generation and analysis assembly 42, optical assembly 60, and/or positioning structure 66. This may include providing any suitable control signal 72 to the one or more other components of the optical probe system and/or receiving any suitable status signal 74 from the one or more other components of the optical probe system. Controller 70 may control the operation of the one or more other components of optical probe system 10 in any suitable manner, such as via controlling the operation of the optical probe system according to any suitable step and/or steps of methods 300, which are discussed in more detail herein.

Controller 70 may include and/or be any suitable structure, device, and/or devices that may be adapted, configured, designed, constructed, and/or programmed to perform the functions discussed herein. As examples, controller 70 may include one or more of an electronic controller, a dedicated controller, a special-purpose controller, a personal computer, a special-purpose computer, a display device, a touch screen display, a logic device, a memory device, and/or a memory device having computer-readable storage media 76.

The computer-readable storage media, when present, also may be referred to herein as non-transitory computer-readable storage media. This non-transitory computer-readable storage media may include, define, house, and/or store computer-executable instructions, programs, and/or code; and these computer-executable instructions may direct optical probe system 10 and/or controller 70 thereof to perform any suitable portion, or subset, of methods 300. Examples of such non-transitory computer-readable storage media include CD-ROMs, disks, hard drives, flash memory, etc. As used herein, storage, or memory, devices and/or media having computer-executable instructions, as well as computer-implemented methods and other methods according to the present disclosure, are considered to be within the scope of subject matter deemed patentable in accordance with Section 101 of Title 35 of the United States Code.

DUT 92 may include any suitable structure that may be supported by DUT support fixture 20, that includes optical devices 94, that includes one or more electrical contact pads 98, and/or that is formed on, formed in, and/or supported by substrate 90. An example of DUT 92 includes an optoelectronic device. Examples of optical devices 94 include grating couplers, waveguides, electromagnetic detectors, and/or electromagnetic emitters. Examples of substrate 90 include a wafer, a semiconductor wafer, a silicon wafer, and/or a Group III-V semiconductor wafer.

As discussed, optical probe assemblies 100 include fiber array unit 200 and array unit fixture 110. As also discussed, the array unit fixture may be configured to be operatively attached to the fiber array unit and/or to support the fiber array unit, such as relative to a remainder of the optical probe system. Examples of array unit fixture 110 include any suitable clamp, receptacle, and/or fastener that may be operatively attached to fiber array unit 200.

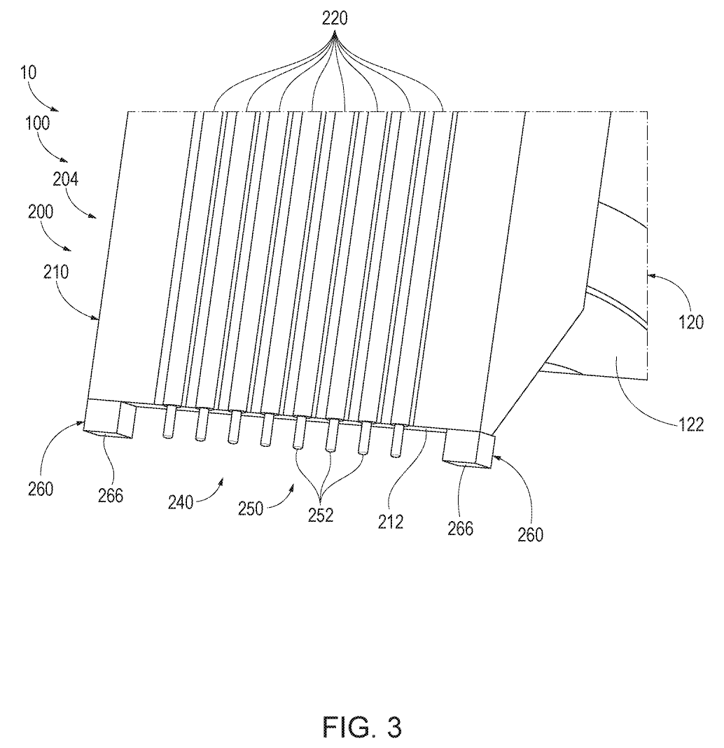

In some examples, and as illustrated in dashed lines in FIG. 1 and in solid lines in FIGS. 2-3, optical probe assemblies 100 may include a capacitive distance sensor 120. Capacitive distance sensor 120 may be configured to detect, or to capacitively detect, a distance between at least a region of the optical probe assembly and the DUT. In a specific example, the capacitive distance sensor may be configured to detect a distance between a DUT-facing sensor surface 122 of the capacitive distance sensor and a front, or an upper, surface of DUT 92. DUT-facing sensor surface 122 may extend parallel, or at least substantially parallel, to a DUT-contacting end region 266 of mechanical coupling structure 260.

In some examples, and as illustrated in dashed lines in FIG. 1, optical probe assembly 100 may include a positioner 130. Positioner 130 may be configured to support array unit fixture 110, to be operatively attached to the array unit fixture, and/or to position, or to precisely position, signal transmission structure 240 relative to optical devices 94. Examples of positioner 130 are disclosed herein with reference to positioning structure 66.

Turning to FIG. 1, with general reference to FIGS. 2-8, and as discussed, fiber array unit 200 includes support body 210 and fiber optic conduits 220, which may be supported by the support body and/or configured to convey electromagnetic signals 32. Fiber array unit 200 also includes signal transmission structure 240, which may be configured to transmit electromagnetic signals 32 between fiber optic conduits 220 and optical devices 94 of DUT 92, and mechanical coupling structure 260, which may be configured to mechanically couple fiber array unit 200 to DUT 92 and/or to maintain transmission gap 262 between signal transmission structure 240 and optical devices 94 and/or DUT 92.

Support body 210 may include any suitable structure that may be adapted, configured, designed, and/or constructed to support and/or to be operatively attached to fiber optic conduits 220, signal transmission structure 240, and/or mechanical coupling structure 260. In some examples, support body 210 may be configured to mechanically support fiber optic conduits 220, such as in a spaced-apart relationship relative to one another. In some examples, fiber optic conduits 220 may be at least partially, or even completely, embedded within support body 210. In some examples, fiber optic conduits 220 may be operatively attached to support body 210.

Support body 210 may be opaque and/or absorptive to electromagnetic signals 32. Additionally or alternatively, support body 210 may define a support body refractive index, which may differ from, or be less than, a fiber optic conduit refractive index of fiber optic conduits 220. Such a configuration may decrease a potential for electromagnetic signals 32 to exit the fiber optic conduits and/or to be conveyed into the support body. As more specific examples, the fiber optic conduit refractive index may be less than 95%, less than 90%, less than 85%, less than 80%, less than 75%, or less than 70% of the fiber optic conduit refractive index.

Fiber optic conduits 220 may include any suitable structure that may be adapted, configured, designed, and/or constructed to convey electromagnetic signals 32. As an example, fiber optic conduits 220 may be transparent, or at least substantially transparent, to electromagnetic signals 32 and/or at a frequency and/or wavelength of electromagnetic signals 32. Examples of the fiber optic conduit refractive index of fiber optic conduits 220 include at least 1, at least 1.1, at least 1.2, at least 1.3, at least 1.4, at least 1.48, at least 1.49, at least 1.5, at least 1.51, at least 1.52, at least 1.53, at least 1.54, at least 1.6, at least 1.8, at least 2, at most 3, at most 2.8, at most 2.6, at most 2.4, at most 2.2, at most 2, at most 1.8, at most 1.6, at most 1.59, at most 1.58, at most 1.57, at most 1.56, at most 1.55, and/or at most 1.54.

Fiber optic conduits 220 may have any suitable relative orientation and/or arrangement within fiber array unit 200. As an example, and within at least a region of the fiber array unit, each fiber optic conduit may extend parallel, or at least substantially parallel, to each other fiber optic conduit.

Signal transmission structure 240 may include any suitable structure that may be adapted, configured, designed, and/or constructed to transmit electromagnetic signals 32 between fiber optic conduits 220 and optical devices 94 of DUT 92. In some examples, signal transmission structure 240, or at least a region of the signal transmission structure, may be configured to receive one or more electromagnetic signals 32, such as provided subset 34, from corresponding fiber optic conduits 220 and to provide the one or more electromagnetic signals to corresponding optical devices 94, such as via and/or across transmission gap 262. Additionally or alternatively, signal transmission structure 240, or at least a region of the signal transmission structure, may be configured to receive one or more electromagnetic signals 32, such as received subset 36, from corresponding optical devices 94, such as via and/or across transmission gap 262, and to provide the one or more electromagnetic signals to corresponding fiber optic conduits 220.

As used herein the phrases “transmission gap” and/or “transmission gap 262” refer to a distance between signal transmission structure 240 and optical devices 94 and/or DUT 92. This distance is free of any physical component of the signal transmission structure, of the optical devices, and/or of the DUT. Instead, transmission gap 262 spans between the signal transmission structure and the optical devices and/or the DUT. Stated differently, the transmission gap refers to a spaced-apart and/or non-contacting relationship between at least a region, or even an entirety, of the signal transmission structure and the optical devices and/or the DUT. In some examples, transmission gap 262 may be referred to herein as and/or may be an air transmission gap 262.

It is within the scope of the present disclosure that the transmission gap may be defined in any suitable direction. As an example, and such as when fiber array unit 200 is configured for surface coupling with optical devices 94, the transmission gap may be defined vertically, may be defined parallel, or at least substantially parallel, to a surface normal direction 96 of DUT 92, and/or may be defined parallel to, at least substantially parallel to, and/or coextensive with a region of signal transmission axis 244 that extends between signal transmission structure 240 and DUT 92. Additionally or alternatively, and such as when fiber array unit 200 is configured for side wall coupling with optical devices 94, transmission gap 262 may be measured horizontally and/or perpendicularly, or at least substantially perpendicularly, to the surface normal direction. Transmission gap 262 additionally or alternatively may be defined as a distance that electromagnetic signals 32 travel between signal transmission structure 240 and corresponding optical devices 94, such as along a signal transmission axis 244.

Each fiber optic conduit 220 may include and/or define a DUT-facing terminal end 226, which may be configured to face toward DUT 92 and/or optical devices 94, such as during operative use of fiber array unit 200 to optically probe the DUT. In some such examples, DUT-facing terminal end 226 of each fiber optic conduit 220 may face toward, or generally toward, a corresponding optical device of the DUT.

It is within the scope of the present disclosure that each DUT-facing terminal end 226 may be a polished, a planar, and/or an at least substantially planar DUT-facing terminal end. In some such examples, the DUT-facing terminal end of each fiber optic conduit 220 may be coplanar, or at least substantially coplanar, with the DUT-facing terminal end of each other fiber optic conduit 220. Additionally or alternatively, the DUT-facing terminal end of each fiber optic conduit may be coplanar, or at least substantially coplanar, with and/or may extend parallel, or at least substantially parallel, to a DUT-facing side 212 of support body 210.

In some examples of fiber array units 200, and as illustrated by the leftmost two fiber optic conduits 220 of FIG. 1 and also by FIGS. 5-8, DUT-facing terminal end 226 of fiber optic conduits 220 may at least partially, or even completely, define signal transmission structure 240. In such a configuration, fiber array unit 200 may be referred to herein as and/or may be a polished fiber array 202. In such a configuration, transmission gap 262 may be defined between DUT-facing terminal end 226 and DUT 92 and/or between DUT-facing side 212 of support body 210 and DUT 92.

Additionally or alternatively, and as illustrated by the rightmost three fiber optic conduits 220 of FIG. 1, signal transmission structure 240 may include a lens assembly 250 that includes a plurality of lenses 252. In such a configuration, fiber array unit 200 also may be referred to herein as and/or may be a lensed fiber array 204. Each lens 252 may be configured to convey a corresponding electromagnetic signal 32 between a corresponding optical device 94 and a corresponding fiber optic conduit 220. In some examples, DUT-facing terminal end 226 of fiber optic conduits 220 may form and/or define lenses 252. Additionally or alternatively, lens assembly 250, including lenses 252, may be operatively attached to the fiber array unit, such as to DUT-facing side 212 of support body 210. Each lens 252 may extend past DUT-facing side 212 of support body 210, such as by a signal transmission structure extension distance 242. In such a configuration, transmission gap 262 may be defined between lenses 252, or a terminal end of lenses 252, and DUT 92.

Signal transmission structure 240 may be configured to transmit each electromagnetic signal 32 across transmission gap 262 along a corresponding signal transmission axis 244. The signal transmission axis may extend at transmission angle 246 relative to surface normal direction 96, with surface normal direction 96 being defined as normal to an upper surface of DUT 92 and/or normal to a plane that extends parallel to the upper surface of the DUT. Examples of transmission angle 246 include at least 5 degrees, at least 6 degrees, at least 7 degrees, at least 8 degrees, at least 9 degrees, at least 10 degrees, at least 11 degrees, at least 12 degrees, at most 18 degrees, at most 17 degrees, at most 16 degrees, at most 15 degrees, at most 14 degrees, at most 13 degrees, at most 12 degrees, at most 11 degrees, and/or at most 10 degrees.

Mechanical coupling structure 260 may include any suitable structure that may be adapted, configured, designed, and/or constructed to mechanically couple fiber array unit 200 to DUT 92 and/or to maintain transmission gap 262 between the signal transmission structure and optical devices 94 and/or DUT 92. Mechanical coupling structure 260 may form a portion of fiber array unit 200, may be directly attached to support body 210, may extend from DUT-facing side 212 of support body 210, may mechanically couple fiber array unit 200 to DUT 92, may directly couple fiber array unit 200 to DUT 92, may directly and mechanically couple fiber array unit 200 to DUT 92, and/or may physically contact DUT 92. Stated differently, mechanical coupling structure 260 is separate and/or distinct from conventional structures of a conventional optical probe system that might contact a DUT but that do not provide mechanical coupling and/or reduce relative motion between a conventional fiber array unit, which does not include mechanical coupling structure 260, and the DUT. In some examples, mechanical coupling structure 260 may be configured to reduce a signal-to-noise ratio for optical measurements performed by optical probe systems 10 and/or utilizing fiber array units 200 by at least 0.05 decibels (dB), at least 0.1 dB, at least 0.2 dB, at least 0.3 dB, at least 0.4 dB, at least 0.5 dB, at least 0.6 dB, at least 0.7 dB, at least 0.8 dB, at least 0.9 dB, or at least 1 dB when compared to a corresponding conventional optical probe system that does not include fiber array units 200 with mechanical coupling structures 260, according to the present disclosure.

As illustrated in FIGS. 1 and 4-8, and with general reference to FIGS. 2-3, mechanical coupling structure 260 may extend from and/or past DUT-facing side 212 of support body 210 a coupling structure extension distance 264. In some examples, such as when fiber array unit 200 is configured for surface coupling with DUT 92, coupling structure extension distance 264 may be greater than signal transmission structure extension distance 242 of signal transmission structure 240 from DUT-facing side 212 of support body 210. In such a configuration, a gap length of transmission gap 262 may be proportional to, based upon, equal to, or at least substantially equal to a difference between the coupling structure extension distance and the signal transmission structure extension distance.

In some examples, such as when fiber array unit 200 is configured for side wall coupling with DUT 92, coupling structure extension distance 264 may be less than signal transmission structure extension distance 242 of signal transmission structure 240 from DUT-facing side 212 of support body 210. In such a configuration, transmission gap 262 may be defined perpendicular, or at least substantially perpendicular, to surface normal direction 96 of DUT 92, as illustrated by the rightmost lens 252 of FIG. 1.

In some examples, mechanical coupling structures 260 may be electrically insulating, DUT-contacting end region 266 may be electrically insulating, and/or the mechanical coupling structures may not be configured to convey electric current to and/or from DUT 92. Such a configuration may decrease a potential for, or even block, electrical communication between optical probe assembly 100 and DUT 92 via mechanical coupling structures 260.

Alternatively, and as discussed, mechanical coupling structures 260 may define one or more electrical probes 40 of optical probe system 10 and/or of optical probe assembly 100. In such a configuration, mechanical coupling structures 260 may be more rigid than conventional electrical probes, thereby permitting and/or facilitating both electrical contact and mechanical coupling via the mechanical coupling structure. Stated differently, and while conventional electrical probes may be configured to deflect, bend, compress, and/or otherwise respond to contact with a corresponding DUT in a manner that permits and/or facilitates overdrive between the conventional electrical probes and the DUT, mechanical coupling structures 260 may not be configured to exhibit a corresponding deflection, bend, and/or compression, as such a configuration decreases an ability of the mechanical coupling structures to function as mechanical coupling structures.

Additionally or alternatively, and while conventional electrical probes may be configured to contact relatively small conventional electrical contact pads, such as electrical contact pads 98 that are discussed in more detail herein, mechanical coupling structures 260 may be substantially larger, such as via exhibiting surface areas of DUT-contacting end region 266 on the order of 10’s or even 100’s of micrometers. Additionally or alternatively, and while conventional electrical probes may be rounded and/or sharpened, such as to permit and/or facilitate penetration of conventional electrical contact pads and/or improved electrical contact with the conventional electrical contact pads, DUT-contacting end region 266 of mechanical coupling structures 260 may be planar, or at least substantially planar, may not be configured to penetrate contact pads 98, and/or may be configured for face-to-face contact with DUTs 92. Such a configuration may increase a surface area for contact between the mechanical coupling structures and the DUT, which may decrease a potential for damage to the DUT due to contact forces between the mechanical coupling structures and the DUT. Stated differently, and while a contact force between an individual mechanical coupling structure 260 and DUT 92 may be relatively higher when compared to the contact force between an individual conventional electrical probe and a corresponding DUT, such as to permit and/or facilitate the mechanical coupling, a contact pressure between the mechanical coupling structures and the DUT may be relatively lower when compared to conventional electrical probes.

In some examples, and as discussed, optical probe systems 10 may include electrical probes 40 that may be operatively attached to and/or configured to move relative to DUT 92 with optical probe system 100 but that are separate and/or distinct from mechanical coupling structures 260. In such a configuration, and to permit and/or facilitate contact and/or overdrive between the electrical probes and corresponding electrical contact pads 98, the optical probe systems may be configured such that the electrical probes contact the corresponding electrical contact pads prior to contact between mechanical coupling structures 260 and the DUT. Stated differently, and when optical probe assembly 100 and/or fiber array unit 200 is moved toward optical devices 94 of DUT 92, such as to establish electrical communication therebetween, electrical probes 40 may electrically contact corresponding electrical contact pads 98 prior to a final, or a minimum magnitude of, transmission gap 262 being established. Stated still differently, electrical probes 40 may extend through a plane that extends through DUT-contacting end regions 266 of mechanical coupling structures 260.

Mechanical coupling structure 260 may have any suitable structure, property, and/or properties. As an example, mechanical coupling structure 260 may be configured to resist deformation when the mechanical coupling structure mechanically couples the fiber array unit to the DUT. As another example, mechanical coupling structure 260 may include and/or be a rigid, or at least substantially rigid, mechanical coupling structure. Such a configuration may decrease a potential for relative motion between fiber array unit 200 and DUT 92 when mechanical coupling structure 260 contacts the DUT. In more specific examples, the mechanical coupling structure may be defined by a coupling structure material, examples of which include a ceramic, a rigid ceramic, a semiconductor material, and a cured photoresist. In some examples, the mechanical coupling structure may be electrically conductive. Alternatively, the mechanical coupling structure may be electrically insulating and/or may be formed from a dielectric material.

In some examples, the coupling structure material may have a low, or a relatively low, coefficient of thermal expansion. Examples of the coefficient of thermal expansion include at most 10 micrometers/meter/̊C, at most 8 micrometers/meter/̊C, at most 6 micrometers/meter/̊C, at most 4 micrometers/meter/̊C, at most 2 micrometers/meter/̊C, at most 1 micrometers/meter/̊C, or at most 0.5 micrometers/meter/̊C. Such a configuration may decrease a potential for changes in a magnitude of transmission gap 262 caused by temperature changes when optical probe system 10 is utilized to optically probe DUT 92.

As illustrated in FIGS. 1 and 3-8, mechanical coupling structure 260 may include at least one DUT-contacting end region 266. In some examples, the mechanical coupling structure may include at least 2, exactly 2, exactly 3, or a plurality of DUT-contacting end regions. In a specific example, the mechanical coupling structure may include a plurality of DUT-contacting end regions 266 that are coplanar, or at least substantially coplanar, with one another. In another specific example, the mechanical coupling structure may include two, or exactly two, DUT-contacting end regions that are spaced apart from one another on DUT-facing side 212 of support body 210. In such a configuration, DUT-facing terminal end 226 of fiber optic conduits 220 may be positioned between the two DUT-contacting end regions.

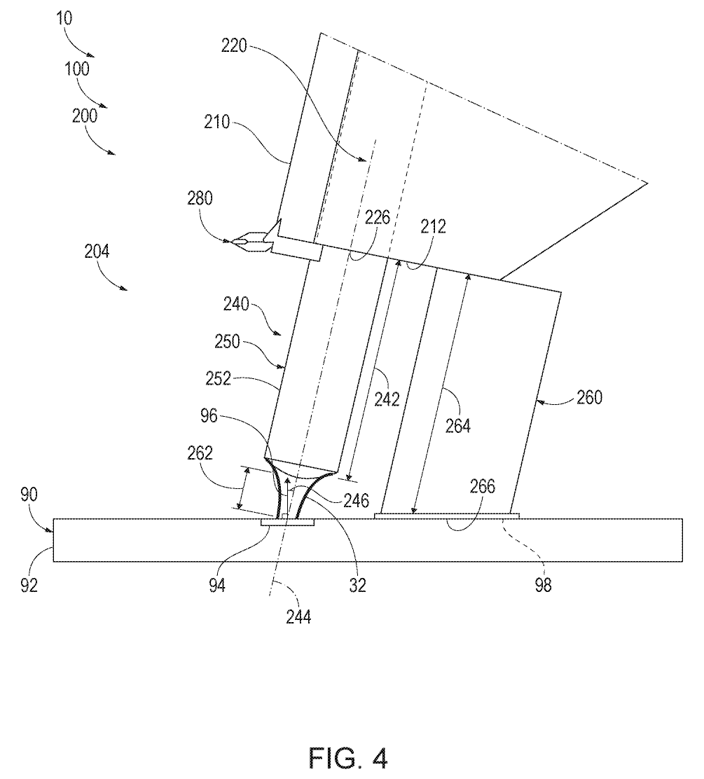

The DUT-contacting end region may be configured to contact DUT 92, such as to permit and/or facilitate mechanical coupling between fiber array unit 200 and the DUT. DUT-contacting end region 266 may have and/or define any suitable shape. As examples, the DUT-contacting end region may be flat, planar, and/or at least substantially planar. As additional examples, the DUT-contacting end region may extend parallel, or at least substantially parallel, to the surface of DUT 92 and/or may be configured for face-to-face contact with the DUT. In a more specific example, and as perhaps best illustrated in FIGS. 4-8, DUT-contacting end region 266 may extend at a complementary, or at least substantially complementary, angle relative to transmission angle 246 of signal transmission axis 244.

It is within the scope of the present disclosure that mechanical coupling structure 260 and/or DUT-contacting end region 266 thereof may be configured to contact DUT 92 at any suitable location. As an example, and as discussed, the mechanical coupling structure may be configured to contact electrical contact pads 98 of the DUT. As another example, the mechanical coupling structure may be configured to contact locations on the DUT that do not include semiconductor devices and/or that are sufficiently mechanically robust to resist damage due to the contact with the mechanical coupling structure.

In some examples, a relative orientation between mechanical coupling structure 260 and signal transmission structure 240, and/or signal transmission axis 244 thereof, may be based, at least in part, on an identity and/or a layout of the DUT. As an example, the relative orientation may be selected to permit optical alignment between the signal transmission structure and optical devices 94 of DUT 92 while avoiding contact between mechanical coupling structure 260 and region(s) of the DUT that would be damaged by such contact. As a more specific example, mechanical coupling structure 260 and signal transmission structure 240 may be oriented, relative to one another, such that the mechanical coupling structure contacts one or more electrical contact pads 98 of DUT 92 when signal transmission structure 240 is optically aligned with corresponding optical devices 94. As another more specific example, mechanical coupling structure 260 and signal transmission structure 240 may be oriented, relative to one another, such that the mechanical coupling structure contacts one or more test structures, test elements, scribe lines, and/or dicing streets of DUT 92 when the signal transmission structure is optically aligned with corresponding optical devices 94.

In some examples, and as illustrated in dashed lines in FIG. 1 and in solid lines in FIG. 4, fiber array unit 200 may include fiducial 280. Fiducial 280, when present, may be adapted, configured, sized, shaped, and/or positioned to be viewed by optical assembly 60 of optical probe system 10, such as to permit and/or facilitate positioning of signal transmission structure 240 relative to optical devices 94. Fiducial 280 may be included within fiber array unit 200 in any suitable manner and/or may be positioned at any suitable location. As examples, the fiducial may be operatively attached to and/or may extend from support body 210 and/or DUT-facing side 212 thereof. Examples of fiducial 280 include a distinctly shaped marking on, engraving in, embossing in, and/or projection from fiber array unit 200. Additional examples of fiducial 280 are disclosed in U.S. Patent Nos. 9,804,196; 10,877,070; and 11,927,603, the complete disclosures of which are hereby incorporated by reference.

Electromagnetic signals 32 may include and/or be any suitable signal that includes electromagnetic radiation. In specific examples, electromagnetic signals 32 may include and/or be optical signals and/or laser light signals.

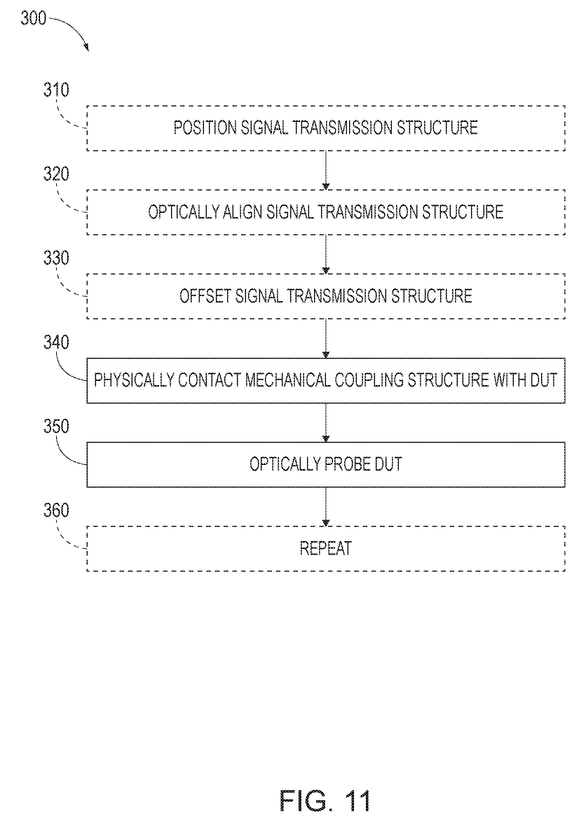

FIG. 11 is a flowchart depicting examples of methods 300, according to the present disclosure, of optically probing a device under test. Methods 300 may be performed with, via, and/or utilizing an optical probe system, an optical assembly, and/or a fiber array unit, examples of which are disclosed herein with reference to optical probe system 10, optical probe assembly 100, and/or fiber array unit 200, respectively. Methods 300 may include positioning a signal transmission structure at 310, optically aligning the signal transmission structure at 320, and/or offsetting the signal transmission structure at 330. Methods 300 include physically contacting a mechanical coupling structure with a device under test (DUT) at 340 and optically probing the DUT at 350. Methods 300 also may include repeating at least a subset of the methods at 360. Examples of the signal transmission structure are disclosed herein with reference to signal transmission structure 240. Examples of the mechanical coupling structure are disclosed herein with reference to mechanical coupling structure 260. Examples of the DUT are disclosed herein with reference to DUT 92.

Positioning the signal transmission structure at 310 may include positioning the signal transmission structure relative to the DUT such that the mechanical coupling structure is spaced apart from the DUT by an alignment separation distance. The signal transmission structure and/or the mechanical coupling structure may form a portion of the fiber array unit, which may form a portion of the optical probe system, and examples of the alignment separation distance are disclosed herein with reference to alignment separation distance 268.

The positioning at 310 may be performed in any suitable manner. As examples, the positioning at 310 may include moving the signal transmission structure into the alignment plane and/or moving the mechanical coupling structure into the alignment plane. Additionally or alternatively, the positioning at 310 may include moving the signal transmission structure relative to the DUT and/or moving the DUT relative to the signal transmission structure.

The positioning at 310 may include establishing any suitable alignment separation distance between the mechanical coupling structure and the DUT. Examples of the separation distance include at least 2 micrometers, at least 4 micrometers, at least 6 micrometers, at least 8 micrometers, at least 10 micrometers, at least 12 micrometers, at least 14 micrometers, at most 20 micrometers, at most 18 micrometers, at most 16 micrometers, at most 14 micrometers, at most 12 micrometers, at most 10 micrometers, at most 8 micrometers, and/or at most 6 micrometers.

The alignment separation distance may be determined in any suitable manner and/or may be based upon any suitable property and/or parameter of the optical probe system, the fiber array unit, and/or the DUT. As examples, the alignment separation distance may be based, at least in part, on an extent of the mechanical coupling structure along the signal transmission axis, at least one optical property of the signal transmission structure, and/or at least one optical property of the plurality of optical devices.

The positioning at 310 may be performed with any suitable timing and/or sequence during methods 300. As examples, the positioning at 310 may be performed prior to and/or at least partially concurrently with the aligning at 320. As additional examples, the positioning at 310 may be performed prior to the offsetting at 330, the physically contacting at 340, and/or the optically probing at 350.

Aligning the signal transmission structure at 320 may include aligning the signal transmission structure with a plurality of optical devices of the DUT to define an aligned-and-spaced relative orientation between the signal transmission structure and the plurality of optical devices. This may include moving the signal transmission structure relative to the DUT and/or moving the DUT relative to the signal transmission structure.

The aligned-and-spaced relative orientation may be defined at the alignment separation distance, within an alignment plane that extends parallel, or at least substantially parallel, to a DUT surface of the DUT, and/or parallel, or at least substantially parallel, to the alignment plane. In such examples, the aligning at 320 may include changing a relative orientation between the signal transmission structure and the plurality of optical devices and/or the DUT within the alignment plane. This may include changing the relative orientation in at least one direction, in two directions, in only two directions, and/or in at most two directions. Additionally or alternatively, the aligning at 320 may include rotating the signal transmission structure and/or the plurality of optical devices within the alignment plane and/or parallel, or at least substantially parallel, to the alignment plane. Stated differently, the aligning at 320 may include maintaining a constant, or at least substantially constant, alignment separation distance during at least a subset, or even an entirety, of the optically aligning at 320.

In some examples, the optically aligning at 320 may include conveying a corresponding optical signal between the signal transmission structure and at least a subset of the plurality of optical devices. In some such examples, the optically aligning may include conveying the corresponding optical signal between the signal transmission structure and each optical device of the plurality of optical devices. This may include conveying the corresponding optical signal along a corresponding signal transmission axis. In some such examples, the aligning at 320 may include iteratively adjusting the relative orientation, such as to increase and/or optimize an efficiency of the conveying. Stated differently, the iteratively adjusting may include determining a relative orientation (e.g., the aligned-and-spaced relative orientation) at which the electromagnetic signal is most effectively and/or efficiently conveyed between the signal transmission structure and a corresponding optical device.

The aligning at 320 may be performed with any suitable timing and/or sequence during methods 300. As examples, the aligning at 320 may be performed at least partially, or even completely, subsequent to the positioning at 310 and/or at least partially, or even completely, prior to the offsetting at 330, the physically contacting at 340, and/or the optically probing at 350.

Offsetting the signal transmission structure at 330 may include offsetting the signal transmission structure from the aligned-and-spaced relative orientation to an offset relative orientation. This may include moving the signal transmission structure relative to the DUT and/or moving the DUT relative to the signal transmission structure. The offset relative orientation may be based, at least in part, on the alignment separation distance and/or on a transmission angle of a signal transmission axis of the signal transmission structure. Examples of the transmission angle and the signal transmission axis are disclosed herein with reference to transmission angle 246 and signal transmission axis 244, respectively.

The offsetting at 330 may include changing the relative orientation between the signal transmission structure and the plurality of optical devices along an offset vector that extends between the aligned-and-spaced relative orientation and the offset relative orientation. The offset vector may extend parallel, or at least substantially parallel, to the alignment plane and/or may extend parallel, or at least substantially parallel, to a projection of the signal transmission axis within the alignment plane. Stated differently, methods 300 may include maintaining a constant, or at least substantially constant, alignment separation distance during at least a subset, or even an entirety, of the offsetting at 330. Stated still differently, the offset relative orientation may be defined within the alignment plane.

In some examples, the offsetting at 330 may include calculating the offset relative orientation. In some such examples, the calculating may include calculating based, at least in part, on both the alignment separation distance and the transmission angle. As more specific examples, the calculating may include calculating such than an offset distance between the aligned-and-spaced relative orientation and the offset relative orientation, within the alignment plane, is proportional to the alignment separation distance, is proportional to the sine of the transmission angle, and/or is equal to the product of the alignment separation distance and the sine of the transmission angle.

The offsetting at 330 may be performed with any suitable timing and/or sequence during methods 300. As examples, the offsetting at 330 may be performed at least partially, or even completely, subsequent to the positioning at 310 and/or to the aligning at 320. As additional examples, the offsetting at 330 may be performed at least partially, or even completely, prior to the physically contacting at 340 and/or the optically probing at 350. As another example, the offsetting at 330 may be performed at least partially concurrently with the physically contacting.

Physically contacting the mechanical coupling structure with the DUT at 340 may include physically contacting to define an aligned-and-contacted relative orientation between the signal transmission structure and the plurality of optical devices in which there is a transmission gap between the signal transmission structure and the plurality of optical devices. Examples of the transmission gap are disclosed herein with reference to transmission gap 262.

The physically contacting at 340 may be performed in any suitable manner. As an example, the physically contacting may include changing the relative orientation between the signal transmission structure and the plurality of optical devices in a contact direction that is perpendicular to the alignment plane and/or that is parallel to a surface normal direction of the DUT. This may include moving the signal transmission structure toward the DUT and/or moving the DUT toward the signal transmission structure.

The physically contacting at 340 may be performed with any suitable timing and/or sequence during methods 300. As examples, the physically contacting at 340 may be performed subsequent to the positioning at 310, the aligning at 320, and/or the offsetting at 330. As additional examples, the physically contacting at 340 may be performed prior to the optically probing at 350 and/or the optical contact may be maintained during the optically probing at 350.

Optically probing the DUT at 350 may include optically probing, or testing, the DUT utilizing the fiber array unit. The optically probing at 350 may be performed in any suitable manner. As an example, the optically probing at 350 may include transmitting a plurality of electromagnetic signals between the signal transmission structure and the plurality of optical devices. In some examples, the optically probing at 350 further may include analyzing at least one characteristic of at least a subset of the plurality of electromagnetic signals. This may include analyzing to determine at least one optical property of the optical probe system and/or to determine at least one optical property of the DUT.

The optically probing at 350 may be performed with any suitable timing and/or sequence during methods 300. As examples, the optically probing at 350 may be performed subsequent to the positioning at 310, the aligning at 320, the offsetting at 330, and/or the physically contacting at 340.

Repeating at least the subset of the methods at 360 may include repeating any suitable step and/or steps of methods 300 in any suitable order and/or for any suitable purpose. As an example, the plurality of optical devices may include and/or be a first plurality of optical devices and the DUT may include and/or be a first DUT. In such examples, the repeating at 360 may include separating the mechanical coupling structure from the first DUT and repeating the positioning at 310, the aligning at 320, the offsetting at 330, the physically contacting at 340, and/or the optically probing at 350 to optically probe a second plurality of optical devices. In some examples, the second plurality of optical devices may form a portion of the first DUT. In some examples, the second plurality of optical devices may form a portion of a second DUT that is distinct from the first DUT.

In the present disclosure, several of the illustrative, non-exclusive examples have been discussed and/or presented in the context of flow diagrams, or flow charts, in which the methods are shown and described as a series of blocks, or steps. Unless specifically set forth in the accompanying description, it is within the scope of the present disclosure that the order of the blocks may vary from the illustrated order in the flow diagram, including with two or more of the blocks (or steps) occurring in a different order and/or concurrently. It is also within the scope of the present disclosure that the blocks, or steps, may be implemented as logic, which also may be described as implementing the blocks, or steps, as logics. In some applications, the blocks, or steps, may represent expressions and/or actions to be performed by functionally equivalent circuits or other logic devices. The illustrated blocks may, but are not required to, represent executable instructions that cause a computer, processor, and/or other logic device to respond, to perform an action, to change states, to generate an output or display, and/or to make decisions.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entities in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C,” and “A, B, and/or C” may mean A alone, B alone, C alone, A and B together, A and C together, B and C together, A, B, and C together, and optionally any of the above in combination with at least one other entity.

In the event that any patents, patent applications, or other references are incorporated by reference herein and (1) define a term in a manner that is inconsistent with and/or (2) are otherwise inconsistent with, either the non-incorporated portion of the present disclosure or any of the other incorporated references, the non-incorporated portion of the present disclosure shall control, and the term or incorporated disclosure therein shall only control with respect to the reference in which the term is defined and/or the incorporated disclosure was present originally.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa.

As used herein, the phrase, “for example,” the phrase, “as an example,” and/or simply the term “example,” when used with reference to one or more components, features, details, structures, embodiments, and/or methods according to the present disclosure, are intended to convey that the described component, feature, detail, structure, embodiment, and/or method is an illustrative, non-exclusive example of components, features, details, structures, embodiments, and/or methods according to the present disclosure. Thus, the described component, feature, detail, structure, embodiment, and/or method is not intended to be limiting, required, or exclusive/exhaustive; and other components, features, details, structures, embodiments, and/or methods, including structurally and/or functionally similar and/or equivalent components, features, details, structures, embodiments, and/or methods, are also within the scope of the present disclosure.

As used herein, “at least substantially,” when modifying a degree or relationship, may include not only the recited “substantial” degree or relationship, but also the full extent of the recited degree or relationship. A substantial amount of a recited degree or relationship may include at least 75% of the recited degree or relationship. For example, an object that is at least substantially formed from a material includes objects for which at least 75% of the objects are formed from the material and also includes objects that are completely formed from the material. As another example, a first length that is at least substantially as long as a second length includes first lengths that are within 75% of the second length and also includes first lengths that are as long as the second length.

Illustrative, non-exclusive examples of fiber array units, optical probe assemblies, optical probe systems, and methods according to the present disclosure are presented in the following enumerated paragraphs. It is within the scope of the present disclosure that an individual step of a method recited herein, including in the following enumerated paragraphs, may additionally or alternatively be referred to as a “step for” performing the recited action.

A1. A fiber array unit for optically testing a plurality of optical devices of a device under test (DUT), the fiber array unit comprising:
a support body;
a plurality of fiber optic conduits supported by the support body and configured to convey a plurality of electromagnetic signals;
a signal transmission structure configured to transmit the plurality of electromagnetic signals between the plurality of fiber optic conduits and the plurality of optical devices; and
a mechanical coupling structure configured to mechanically couple, or directly mechanically couple, the fiber array unit to the DUT and to maintain a transmission gap between the signal transmission structure and at least one, and optionally both, of:
   (i) the plurality of optical devices; and
   (ii) the DUT.

A2. The fiber array unit of paragraph A1, wherein the support body is configured to mechanically support the plurality of fiber optic conduits, optionally in a spaced-apart relationship relative to one another.

A3. The fiber array unit of any of paragraphs A1-A2, wherein the plurality of fiber optic conduits is at least partially, or even completely, embedded within the support body.

A4. The fiber array unit of any of paragraphs A1-A3, wherein the plurality of fiber optic conduits is operatively attached to the support body.

A5. The fiber array unit of any of paragraphs A1-A4, wherein the support body defines a support body refractive index that is less than a fiber optic conduit refractive index of the plurality of fiber optic conduits.

A6. The fiber array unit of any of paragraphs A1-A5, wherein the plurality of fiber optic conduits has a/the fiber optic conduit refractive index of at least one of:
(i) at least 1, at least 1.1, at least 1.2, at least 1.3, at least 1.4, at least 1.48, at least 1.49, at least 1.5, at least 1.51, at least 1.52, at least 1.53, at least 1.54, at least 1.6, at least 1.8, or at least 2; and
(ii) at most 3, at most 2.8, at most 2.6, at most 2.4, at most 2.2, at most 2, at most 1.8, at most 1.6, at most 1.59, at most 1.58, at most 1.57, at most 1.56, at most 1.55, or at most 1.54.

A7. The fiber array unit of any of paragraphs A1-A6, wherein, within at least a region of the fiber array unit, each fiber optic conduit of the plurality of fiber optic conduits extends parallel, or at least substantially parallel, to each other fiber optic conduit of the plurality of fiber optic conduits.

A8. The fiber array unit of any of paragraphs A1-A7, wherein the signal transmission structure is configured to transmit the plurality of electromagnetic signals between the plurality of fiber optic conduits and the plurality of optical devices via, or across, the transmission gap.

A9. The fiber array unit of any of paragraphs A1-A8, wherein the transmission gap includes, or is, an air transmission gap.

A10. The fiber array unit of any of paragraphs A1-A9, wherein at least a region of the signal transmission structure is spaced-apart from the DUT to define the transmission gap.

A11. The fiber array unit of any of paragraphs A1-A10, wherein each fiber optic conduit of the plurality of fiber optic conduits includes a DUT-facing terminal end configured to face toward the plurality of optical devices.

A12. The fiber array unit of paragraph A11, wherein the DUT-facing terminal end includes at least one of a polished end region, a planar end region, and an at least substantially planar end region.

A13. The fiber array unit of any of paragraphs A11-A12, wherein the DUT-facing terminal end of each fiber optic conduit at least one of:
(i) is coplanar, or at least substantially coplanar, with the DUT-facing terminal end of each other fiber optic conduit of the plurality of fiber optic conduits;
(ii) is coplanar, or at least substantially coplanar, with a DUT-facing side of the support body; and
(iii) extends parallel, or at least substantially parallel, to the DUT-facing side of the support body.

A14. The fiber array unit of any of paragraphs A11-A13, wherein the DUT-facing terminal end at least partially, or completely, defines the signal transmission structure.

A15. The fiber array unit of paragraph A14, wherein the fiber array unit includes, or is, a polished fiber array.

A16. The fiber array unit of any of paragraphs A11-A15, wherein the signal transmission structure includes a lens assembly that includes a plurality of lenses, wherein each lens of the plurality of lenses is configured to convey a corresponding electromagnetic signal between a corresponding optical device and a corresponding fiber optic conduit of the plurality of fiber optic conduits.

A17. The fiber array unit of paragraph A16, wherein the DUT-facing terminal end of each fiber optic conduit defines a corresponding lens of the plurality of lenses.

A18. The fiber array unit of any of paragraphs A16-A17, wherein the lens assembly is operatively attached to the fiber array unit.

A19. The fiber array unit of any of paragraphs A16-A18, wherein each lens of the plurality of lenses extends past a DUT-facing side of the support body.

A19.1. The fiber array unit of any of paragraphs A16-A19, wherein the fiber array unit includes, or is, a lensed fiber array.

A20. The fiber array unit of any of paragraphs A1-A19.1, wherein the signal transmission structure is configured to transmit the plurality of electromagnetic signals across the transmission gap along a signal transmission axis that extends at a transmission angle relative to a surface normal direction of the DUT, optionally wherein the transmission angle is at least one of:
(i) at least 5 degrees; at least 6 degrees; at least 7 degrees, at least 8 degrees, at least 9 degrees, at least 10 degrees, at least 11 degrees, or at least 12 degrees; and
(ii) at most 18 degrees, at most 17 degrees, at most 16 degrees, at most 15 degrees, at most 14 degrees, at most 13 degrees, at most 12 degrees, at most 11 degrees, or at most 10 degrees.

A21. The fiber array unit of any of paragraphs A1-A20, wherein the mechanical coupling structure is configured to physically contact the DUT to mechanically couple the fiber array unit to the DUT.

A22. The fiber array unit of any of paragraphs A1-A21, wherein the mechanical coupling structure extends a coupling structure extension distance from a/the DUT-facing side of the support body.

A23. The fiber array unit of paragraph A22, wherein the coupling structure extension distance is greater than a signal transmission structure extension distance of the signal transmission structure from the DUT-facing side of the support body.

A24. The fiber array unit of paragraph A23, wherein a gap length of the transmission gap is at least one of:
(i) proportional to, based upon, equal to, or at least substantially equal to a difference between the coupling structure extension distance and the signal transmission structure extension distance; and
(ii) defined parallel, or at least substantially parallel, to a/the surface normal direction of the DUT.

A25. The fiber array unit of any of paragraphs A23-A24, wherein the fiber array unit is configured for surface coupling with the DUT.

A26. The fiber array unit of paragraph A22, wherein the coupling structure extension distance is less than a signal transmission structure extension distance of the signal transmission structure from the DUT-facing side of the support body.

A27. The fiber array unit of paragraph A26, wherein a gap length of the transmission gap is defined perpendicular, or at least substantially perpendicular, to a/the surface normal direction of the DUT.

A28. The fiber array unit of any of paragraphs A26-A27, wherein the fiber array unit is configured for side wall coupling with the DUT.

A29. The fiber array unit of any of paragraphs A1-A28, wherein the mechanical coupling structure is a rigid, or at least substantially rigid, mechanical coupling structure.

A30. The fiber array unit of any of paragraphs A1-A29, wherein the mechanical coupling structure is defined by a coupling structure material.

A31. The fiber array unit of paragraph A30, wherein the coupling structure material includes at least one of a ceramic, a rigid ceramic, a semiconductor material, and a cured photoresist.

A32. The fiber array unit of any of paragraphs A30-A31, wherein the coupling structure material has a low coefficient of thermal expansion.

A33. The fiber array unit of any of paragraphs A1-A32, wherein the mechanical coupling structure is configured to resist deformation when the mechanical coupling structure mechanically couples the fiber array unit to the DUT.

A34. The fiber array unit of any of paragraphs A1-A33, wherein the mechanical coupling structure defines at least one DUT-contacting end region configured to contact the DUT, optionally wherein the at least one DUT-contacting end region includes a plurality, at least two, two, or three DUT-contacting end regions.

A35. The fiber array unit of paragraph A34, wherein the at least one DUT-contacting end region is a planar, or at least substantially planar, DUT-contacting end region.

A36. The fiber array unit of any of paragraphs A34-A35, wherein the at least one DUT-contacting end region includes a plurality of DUT-contacting end regions that are coplanar with one another.

A37. The fiber array unit of any of paragraphs A34-A36, wherein the at least one DUT-contacting end region is oriented to define a face-to-face contact with the DUT when the mechanical coupling structure mechanically couples the fiber array unit to the DUT.

A38. The fiber array unit of any of paragraphs A34-A37, wherein the at least one DUT-contacting end region extends at a complementary angle relative to a/the transmission angle of a/the signal transmission axis of the plurality of electromagnetic signals.

A39. The fiber array unit of any of paragraphs A34-A38, wherein the mechanical coupling structure defines two DUT-contacting end regions spaced-apart from one another along a/the DUT-facing side of the support body.

A40. The fiber array unit of paragraph A39, wherein a/the DUT-facing terminal end of each fiber optic conduit of the plurality of fiber optic conduits is positioned between the two DUT-contacting end regions.

A40.1. The fiber array unit of any of paragraphs A1-A40, wherein the mechanical coupling structure is an electrically conductive mechanical coupling structure.

A40.1.1. The fiber array unit of paragraph A40.1, wherein the mechanical coupling structure defines an electrical probe configured for electrical communication with the DUT.

A40.2. The fiber array unit of any of paragraphs A1-A40.1.1., wherein the mechanical coupling structure is at least one of an electrically insulating mechanical coupling structure and a dielectric mechanical coupling structure.

A41. The fiber array unit of any of paragraphs A1-A40.2., wherein the fiber array unit further includes a fiducial configured to be viewed by an optical assembly to facilitate positioning the signal transmission structure relative to the plurality of optical devices.

A42. The fiber array unit of paragraph A41, wherein the fiducial extends from a/the DUT-facing side of the support body.

A43. The fiber array unit of any of paragraphs A1-A42, wherein the DUT is at least one of formed on a substrate, formed in the substrate, and supported by the substrate.

A44. The fiber array unit of paragraph A43, wherein the substrate includes at least one of a wafer, a semiconductor wafer, a silicon wafer, and a Group III-V semiconductor wafer.

A45. The fiber array unit of any of paragraphs A1-A44, wherein the DUT includes at least one of an optical device and an optoelectronic device.

A46. The fiber array unit of any of paragraphs A1-A45, wherein the plurality of optical devices includes at least one of a plurality of grating couplers, a plurality of waveguides, a plurality of electromagnetic detectors, and a plurality of electromagnetic signal emitters.

A47. The fiber array unit of any of paragraphs A1-A46, wherein the plurality of electromagnetic signals includes a plurality of optical signals.

A48. The fiber array unit of any of paragraphs A1-A47, wherein a relative orientation between the signal transmission structure and the mechanical coupling structure is based, at least in part, on a layout of the DUT.

B1. An optical probe assembly, comprising:
the fiber array unit of any of paragraphs A1-A48; and
an array unit fixture configured to be operatively attached to the fiber array unit and to support the fiber array unit.

B2. The optical probe assembly of paragraph B1, wherein the optical probe assembly further includes a capacitive distance sensor configured to capacitively detect a distance between at least a region of the optical probe assembly and the DUT.

B3. The optical probe assembly of paragraphB2, wherein the capacitive distance sensor defines a DUT-facing sensor surface that extends parallel, or at least substantially parallel, to a/the at least one DUT-contacting end region of the mechanical coupling structure.

B4. The optical probe assembly of any of paragraphs B1-B3, wherein the optical probe assembly further includes a positioner configured to support the array unit fixture and to precisely position the signal transmission structure relative to the plurality of optical devices of the DUT.

C1. An optical probe system, comprising:
the optical probe assembly of any of paragraphs B1-B4;
a DUT support fixture configured to operatively support the DUT relative to the optical probe assembly;
an electromagnetic signal generation and analysis assembly configured to at least one of provide at least a provided subset of the plurality of electromagnetic signals to a corresponding providing subset of the plurality of fiber optic conduits and receive at least a received subset of the plurality of electromagnetic signals from a corresponding receiving subset of the plurality of fiber optic conduits.

C2. The optical probe system of paragraph C1, wherein the DUT support fixture is configured to operatively support the DUT in the form of at least one of a singulated DUT and a packaged DUT.

C3. The optical probe system of any of paragraphs C1-C2, wherein the DUT support fixture includes a chuck configured to support a/the substrate that includes the DUT.

C4. The optical probe system of any of paragraphs C1-C3, wherein the optical probe system further includes at least one electrical probe configured to at least one of provide an electric test signal to the DUT, provide an electric power signal to the DUT, and receive an electric resultant signal from the DUT.

C4.1. The optical probe system of paragraph C4, wherein the at least one electrical probe is spaced apart from the mechanical coupling structure.

C4.2. The optical probe system of any of paragraphs C4-C4.1, wherein the at least one electrical probe extends through a plane that that extends through a/the DUT-contacting end region of the mechanical coupling structure.

C5. The optical probe system of paragraph C4, wherein the mechanical coupling structure defines the at least one electrical probe.

C6. The optical probe system of any of paragraphs C4-C5, wherein the at least one electrical probe forms a portion of the DUT support fixture.

C7. The optical probe system of any of paragraphs C4-C6, wherein the optical probe system further includes an electric signal generation and analysis assembly configured to at least one of provide the electric test signal to the at least one electrical probe, provide the electric power signal to the at least one electrical probe; and receive the electric resultant signal from the at least one electrical probe.

C8. The optical probe system of any of paragraphs C1-C7, wherein the optical probe system further includes an/the optical assembly configured to collect an optical image of at least one of the DUT support fixture, the DUT, the fiber array unit, and a/the fiducial of the fiber array unit.

C9. The optical probe system of any of paragraphs C1-C8, wherein the optical probe system further includes the DUT, wherein the DUT is supported by the DUT support fixture.

C10. The optical probe system of any of paragraphs C1-C9, wherein the optical probe system further includes a positioning structure configured to at least one of translate and rotate the fiber array unit and the DUT support fixture relative to one another.

C11. The optical probe system of any of paragraphs C1-C10, wherein the optical probe system further includes a controller programmed to control the operation of the optical probe system according to any suitable step and/or steps of any of the methods of any of paragraphs D1-D29.

D1. A method of optically probing a device under test (DUT), the method comprising:
optionally positioning a signal transmission structure of a fiber array unit of an optical probe system relative to the DUT such that a mechanical coupling structure of the fiber array unit is spaced apart from the DUT by an alignment separation distance;
optionally subsequent to the positioning, optically aligning the signal transmission structure with a plurality of optical devices of the DUT to define an aligned-and-spaced relative orientation between the signal transmission structure and the plurality of optical devices, optionally wherein the aligned-and-spaced relative orientation is defined at least one of at the alignment separation distance, within an alignment plane that extends parallel, or at least substantially parallel, to a DUT surface of the DUT, and parallel, or at least substantially parallel, to the alignment plane;
optionally subsequent to the optically aligning, offsetting the signal transmission structure from the aligned-and-spaced relative orientation to an offset relative orientation that is based, at least in part, on both the alignment separation distance and a transmission angle of a signal transmission axis of the signal transmission structure;
physically contacting the mechanical coupling structure with the DUT to define an aligned-and-contacted relative orientation between the signal transmission structure and the plurality of optical devices in which there is a transmission gap between the signal transmission structure and the plurality of optical devices; and
optically probing the DUT utilizing the fiber array unit.

D2. The method of paragraph D1, wherein the positioning includes at least one of:
(i) moving the signal transmission structure into the alignment plane; and
(ii) moving the mechanical coupling structure into the alignment plane.

D3. The method of any of paragraphs D1-D2, wherein the alignment separation distance is at least one of:
(i) at least 2 micrometers, at least 4 micrometers, at least 6 micrometers, at least 8 micrometers, at least 10 micrometers, at least 12 micrometers, or at least 14 micrometers; and
(ii) at most 20 micrometers, at most 18 micrometers, at most 16 micrometers, at most 14 micrometers, at most 12 micrometers, at most 10 micrometers, at most 8 micrometers, or at most 6 micrometers.

D4. The method of any of paragraphs D1-D3, wherein the alignment separation distance is based, at least in part, on at least one of:
(i) an extent of the mechanical coupling structure along the signal transmission axis;
(ii) at least one optical property of the signal transmission structure; and
(iii) at least one optical property of the plurality of optical devices.

D5. The method of any of paragraphs D1-D4, wherein the positioning includes at least one of:
(i) moving the signal transmission structure relative to the DUT; and
(ii) moving the DUT relative to the signal transmission structure.

D6. The method of any of paragraphs D1-D5, wherein the optically aligning includes changing a relative orientation between the signal transmission structure and the plurality of optical devices within the alignment plane.

D7. The method of paragraph D6, wherein the changing includes changing the relative orientation in at least one of one direction, at least one direction, two directions, only two directions, and at most two directions.

D8. The method of any of paragraphs D6-D7, wherein the changing includes rotating at least one of the signal transmission structure and the plurality of optical devices parallel, or at least substantially parallel, to the alignment plane.

D9. The method of any of paragraphs D1-D8, wherein the optically aligning includes maintaining a constant, or at least substantially constant, alignment separation distance during at least a subset, or an entirety, of the optically aligning.

D10. The method of any of paragraphs D1-D9, wherein the optically aligning includes conveying a corresponding optical signal of a plurality of optical signals between the signal transmission structure and at least a subset of the plurality of optical devices, or each optical device of the plurality of optical devices.

D11. The method of paragraph D10, wherein the conveying the corresponding optical signal includes conveying along a corresponding signal transmission axis.

D12. The method of any of paragraphs D10-D11, wherein the optically aligning further includes iteratively adjusting the relative orientation to increase, or optimize, an efficiency of the conveying.

D13. The method of any of paragraphs D1-D12, wherein the optically aligning includes at least one of:
(i) moving the signal transmission structure relative to the DUT; and
(ii) moving the DUT relative to the signal transmission structure.

D14. The method of any of paragraphs D1-D13, wherein the offsetting includes changing a/the relative orientation between the signal transmission structure and the plurality of optical devices along an offset vector that extends between the aligned-and-spaced relative orientation and the offset relative orientation.

D15. The method of paragraph D14, wherein the offset vector at least one of:
(i) extends parallel, or at least substantially parallel, to the alignment plane; and
(ii) extends parallel, or at least substantially parallel, to a projection of the signal transmission axis within the alignment plane.

D16. The method of any of paragraphs D1-D15, wherein the method includes maintaining a constant, or at least substantially constant, alignment separation distance during at least a subset, or an entirety, of the offsetting.

D17. The method of any of paragraphs D1-D16, wherein the offset relative orientation is defined within the alignment plane.

D18. The method of any of paragraphs D1-D17, wherein the offsetting is at least one of:
(i) performed at least partially concurrent with the physically contacting; and
(ii) performed prior to the contacting.

D19. The method of any of paragraphs D1-D18, wherein the offsetting includes calculating the offset relative orientation based upon both the alignment separation distance and the transmission angle.

D20. The method of paragraph D19, wherein the calculating includes calculating such that an offset distance between the aligned-and-spaced relative orientation and the offset relative orientation, within the alignment plane, is at least one of:
(i) proportional to the alignment separation distance;
(ii) proportional to sin(transmission angle); and

(iii) equal to (alignment separation distance)*sin(transmission angle).

D21. The method of any of paragraphs D1-D20, wherein the offsetting includes at least one of:
(i) moving the signal transmission structure relative to the DUT; and
(ii) moving the DUT relative to the signal transmission structure.

D22. The method of any of paragraphs D1-D21, wherein the physically contacting includes changing a/the relative orientation between the signal transmission structure and the plurality of optical devices in a contact direction that is perpendicular to the alignment plane.

D23. The method of any of paragraphs D1-D22, wherein the physically contacting includes at least one of:
(i) moving the signal transmission structure toward the DUT; and
(ii) moving the DUT toward the signal transmission structure.

D24. The method of any of paragraphs D1-D23, wherein the optically probing includes transmitting a plurality of electromagnetic signals between the signal transmission structure and the plurality of optical devices.

D25. The method of paragraph D24, wherein the optically probing further includes analyzing at least one characteristic of at least a subset of the plurality of electromagnetic signals to determine at least one of:
(i) at least one optical property of the optical probe system; and
(ii) at least one optical property of the DUT.

D26. The method of any of paragraphs D1-D25, wherein the plurality of optical devices is a first plurality of optical devices, wherein the DUT is a first DUT, and further wherein the method includes separating the mechanical coupling structure from the first DUT and repeating the positioning, the optically aligning, the offsetting, the mechanically coupling, and the optically probing to optically probe a second plurality of optical devices.

D27. The method of paragraph D26, wherein at least one of:
(i) the second plurality of optical devices form a portion of the first DUT; and
(ii) the second plurality of optical devices form a portion of a second DUT that is distinct from the first DUT.

D28. The method of any of paragraphs D1-D27, wherein the fiber array unit includes any suitable structure, function, and/or feature of any of the fiber array units of any of paragraphs A1-A48.

D29. The method of any of paragraphs D1-D28, wherein the optical probe system includes any suitable structure, function, and/or feature of any of the optical probe assemblies of any of paragraphs B1-B4 and/or of any of the optical probe systems of any of paragraphs C1-C11.

D30. Non-transitory computer-readable storage media including computer-readable instructions that, when executed, direct an optical probe system to perform any suitable step and/or steps of any of the methods of any of paragraphs D1-D29.

### Industrial Applicability

The fiber array units, optical probe assemblies, optical probe systems, and methods disclosed herein are applicable to the semiconductor manufacturing and test industries.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. A fiber array unit for optically testing a plurality of optical devices of a device under test (DUT), the fiber array unit comprising:
a support body;
a plurality of fiber optic conduits supported by the support body and configured to convey a plurality of electromagnetic signals;
a signal transmission structure configured to transmit the plurality of electromagnetic signals between the plurality of fiber optic conduits and the plurality of optical devices; and
a mechanical coupling structure configured to mechanically couple the fiber array unit to the DUT and to maintain a transmission gap between the signal transmission structure and the plurality of optical devices.

2. The fiber array unit of claim 1, wherein the mechanical coupling structure is configured to physically contact the DUT to mechanically couple the fiber array unit to the DUT.

3. The fiber array unit of claim 1, wherein the mechanical coupling structure extends a coupling structure extension distance from a DUT-facing side of the support body.

4. The fiber array unit of claim 3, wherein the coupling structure extension distance is greater than a signal transmission structure extension distance of the signal transmission structure from the DUT-facing side of the support body.

5. The fiber array unit of claim 4, wherein the fiber array unit is configured for surface coupling with the DUT.

6. The fiber array unit of claim 3, wherein the coupling structure extension distance is less than a signal transmission structure extension distance of the signal transmission structure from the DUT-facing side of the support body.

7. The fiber array unit of claim 6, wherein the fiber array unit is configured for side wall coupling with the DUT.

8. The fiber array unit of claim 1, wherein the mechanical coupling structure is an at least substantially rigid mechanical coupling structure.

9. The fiber array unit of claim 1, wherein the mechanical coupling structure is defined by a coupling structure material, wherein the coupling structure material includes at least one of a ceramic, a rigid ceramic, a semiconductor material, and a cured photoresist.

10. The fiber array unit of claim 1, wherein the mechanical coupling structure is configured to resist deformation when the mechanical coupling structure mechanically couples the fiber array unit to the DUT.

11. The fiber array unit of claim 1, wherein the mechanical coupling structure defines at least one DUT-contacting end region configured to contact the DUT, wherein the at least one DUT-contacting end region is an at least substantially planar DUT-contacting end region.

12. The fiber array unit of claim 11, wherein the at least one DUT-contacting end region is oriented to define a face-to-face contact with the DUT when the mechanical coupling structure mechanically couples the fiber array unit to the DUT.

13. The fiber array unit of claim 11, wherein the at least one DUT-contacting end region extends at a complementary angle relative to a transmission angle of a signal transmission axis of the plurality of electromagnetic signals.

14. The fiber array unit of claim 11, wherein the mechanical coupling structure defines two DUT-contacting end regions spaced apart from one another along a DUT-facing side of the support body, wherein a DUT-facing terminal end of each fiber optic conduit of the plurality of fiber optic conduits is positioned between the two DUT-contacting end regions.

15. The fiber array unit of claim 1, wherein the mechanical coupling structure is an electrically conductive mechanical coupling structure.

16. The fiber array unit of claim 1, wherein the mechanical coupling structure is at least one of an electrically insulating mechanical coupling structure and a dielectric mechanical coupling structure.

17. The fiber array unit of claim 1, wherein each fiber optic conduit of the plurality of fiber optic conduits includes a DUT-facing terminal end configured to face toward the plurality of optical devices.

18. The fiber array unit of claim 17, wherein the DUT-facing terminal end includes at least one of a polished end region, a planar end region, and an at least substantially planar end region.

19. The fiber array unit of claim 17, wherein the DUT-facing terminal end at least partially defines the signal transmission structure.

20. The fiber array unit of claim 17, wherein the signal transmission structure includes a lens assembly that includes a plurality of lenses, wherein each lens of the plurality of lenses is configured to convey a corresponding electromagnetic signal between a corresponding optical device and a corresponding fiber optic conduit of the plurality of fiber optic conduits.

21. The fiber array unit of claim 20, wherein the DUT-facing terminal end of each fiber optic conduit defines a corresponding lens of the plurality of lenses.

22. The fiber array unit of claim 20, wherein each lens of the plurality of lenses extends past a DUT-facing side of the support body.

23. An optical probe assembly, comprising:
the fiber array unit of claim 1; and
an array unit fixture configured to be operatively attached to the fiber array unit and to support the fiber array unit.

24. An optical probe system, comprising:
the optical probe assembly of claim 23;
a DUT support fixture configured to operatively support the DUT relative to the optical probe assembly;
an electromagnetic signal generation and analysis assembly configured to at least one of provide at least a provided subset of the plurality of electromagnetic signals to a corresponding providing subset of the plurality of fiber optic conduits and receive at least a received subset of the plurality of electromagnetic signals from a corresponding receiving subset of the plurality of fiber optic conduits.

25. A method of optically probing a device under test (DUT), the method comprising:
positioning a signal transmission structure of a fiber array unit of an optical probe system relative to the DUT such that a mechanical coupling structure of the fiber array unit is spaced apart from the DUT by an alignment separation distance;
subsequent to the positioning, optically aligning the signal transmission structure with a plurality of optical devices of the DUT to define an aligned-and-spaced relative orientation between the signal transmission structure and the plurality of optical devices;
subsequent to the optically aligning, offsetting the signal transmission structure from the aligned-and-spaced relative orientation to an offset relative orientation that is based, at least in part, on both the alignment separation distance and a transmission angle of a signal transmission axis of the signal transmission structure;
physically contacting the mechanical coupling structure with the DUT to define an aligned-and-contacted relative orientation between the signal transmission structure and the plurality of optical devices in which there is a transmission gap between the signal transmission structure and the plurality of optical devices; and
optically probing the DUT utilizing the fiber array unit.
